(19) United States
(12) Patent Application Publication
(10) Pub. No.: US 2016/0027828 A1
(43) Pub. Date: Jan. 28, 2016

(54) Image Sensors

(71) Applicant: Samsung Electronics Co., Ltd., Suwon-si (KR)

(72) Inventors: Seok-ha Lee, Hwaseong-si (KR); Hyun-pil Noh, Seongnam-si (KR)

(21) Appl. No.: 14/799,110

(22) Filed: Jul. 14, 2015

(30) Foreign Application Priority Data
Jul. 25, 2014 (KR) 10-2014-0095004

(51) Int. Cl. H01L 27/146

(52) U.S. Cl. CPC H01L 27/14623; H01L 27/14643; H01L 27/14638; H01L 27/14616

(57) ABSTRACT

Image sensors are provided. The image sensors can include a photodiode in a substrate configured to generate signal charges based on incident light, a charge storage unit positioned at a side of the photodiode configured to temporarily store the signal charges generated by the photodiode, and a shield metal on the charge storage unit and on the substrate.

### CROSS-REFERENCE TO RELATED APPLICATIONS

This application claims the benefit of Korean Patent Application No 10-2014-0095004, filed on Jul. 25, 2014, in the Korean intellectual Property Office, the disclosure of which is incorporated by reference herein in its entirety.

### BACKGROUND

The inventive concept relates to image sensors, and more particularly, to image sensors including a charge storage unit positioned at one side of a photodiode to temporarily store charges generated in the photodiode and a shield metal for blocking light that is input into the charge storage unit.

Image sensors are semiconductor devices for converting incident light into an electrical signal. The image sensor adopts a switching method of detecting an output by using metal oxide semiconductor (MOS) driving transistors corresponding to the number of pixels of the image sensor. Image sensors are used in various devices, such as digital cameras, camcorders, mobile phones, game consoles, security cameras, and medical micro cameras. The image sensor is a sensor for converting an optical image signal into an electrical image signal. In some cases, a charge storage unit for temporarily storing charges generated in a photodiode is disposed at one side of the photodiode to add a global shutter function to the image sensor. In the charge storage unit, the size of a stored signal does not have to be changed while the photodiode receives light to generate signal charges. Accordingly, in order to obtain desired characteristics, a shield metal can be deposited to block light that is input from the outside.

### SUMMARY

The inventive concept provides reliable image sensors in which a shield metal contacts an ion implantation region via a butting contact to thereby prevent or reduce a phenomenon in which excessive ions are implanted in the shield metal, which is floated, while performing a contact process on the shield metal. This phenomenon can cause arcing in facilities or plasma damage to a device under the shield metal.

According to aspects of the present inventive concepts, there is provided an image sensor including a photodiode in a substrate, a charge storage unit positioned at a side of the photodiode, a transfer gate, and a shield metal on the charge storage unit and on the substrate.

The photo diode can be configured to generate signal charges based on incident light. The charge storage unit can be configured to temporarily store signal charges transmitted from the photo ., The transfer gate can be configured to transfer the signal charges stored in the charged storage unit.

The shield metal may be on the substrate at a side of the charge storage unit.

The shield metal may be on the substrate at more than one side of the charge storage unit.

A level of a lower surface of a portion of the shield metal on the substrate may be lower than a level of an upper surface of the substrate.

A portion of the shield metal on the substrate may be a portion of a region in which the photo diode is formed.

The shield metal may extend continuously in a first direction and a second direction.

The shield metal may surround the charge storage unit and may be separate from an adjacent shield metal.

When the substrate is doped with P-type impurities, the shield metal may be connected to a ground voltage.

When the substrate is doped with N-type impurities, the shield metal may be connected to a bias voltage.

The charge storage unit may be a metal oxide semiconductor (MOS) capacitor.

According to other aspects of the present inventive concepts, there is provided an image sensor including a photodiode in a substrate, a charge storage unit formed in the substrate, and a shield metal that surrounds the charge storage unit and contacts the substrate The charge storage unit may be configured to temporarily store signal charges transmitted from the photo diode. The shield metal may contact the substrate via a butting contact.

The butting contact may contact the substrate at one side of the charge storage unit.

The butting contact may form a portion may contact the substrate at more than one side of the charge storage unit.

The butting contact may be formed adjacent an edge of the shield metal.

The butting contact may be formed near a region that is separate from an edge of the shield metal.

A region in which the butting contact contacts the substrate may be a doped region.

According to other aspects of the present inventive concepts, there is provided an image sensor including a substrate, a photodiode in the substrate, a charge storage unit in the substrate and adjacent the photodiode, a gate dielectric film on the substrate, and a shield metal on the charge storage unit and on the substrate. Portions of the shield metal may perforate the gate dielectric film.

The image sensor may also include a channel stop region below the gate dielectric film and contacting lower portions of the charge storage unit. The shield metal may the channel stop region.

The shield metal may perforate the gate dielectric film in at least two regions.

The image sensor may also include an upper insulating film on an upper portion of the charge storage unit and on the photodiode. The shield metal may perforate the upper insulating film.

The shield metal defines a butting contact that may contact a doped region of the substrate below the gate dielectric film. An electrical connection of the shield metal may correspond to a type of doping impurities used in the doped region.

According to other aspects of the present inventive concepts, there is provided an electronic device including an image sensor including a plurality of pixels and a signal processing circuit that processes a signal output from the image sensor. The image sensor can include a photo diode arranged on a substrate, a charge storage unit positioned at one side of the photo diode , a transfer gate that transfers signal charges accumulated in the charge storage unit, and a shield metal that surrounds the charge storage unit and contacts the substrate. The photo diode may be configured to generate signal charges based on incident light. The charge storage unit may be configured to temporarily store signal charges transmitted from the photo diode.

### BRIEF DESCRIPTION OF THE DRAWINGS

Exemplary embodiments of the present inventive concepts will be more clearly understood from the following detailed description taken in conjunction with the accompanying drawings in which:

FIG. 1 is a plan view of image sensors according to embodiments of the present inventive concepts;

FIG. 2 is a cross-sectional view of image sensors, in which a shield metal has a huffing contact formed at both sides of a charge storage unit, according to embodiments of the present inventive concepts;

FIGS. 3 through 14 are diagrams that sequentially illustrate methods of to manufacturing image sensors, in which a shield metal forms a butting contact at both sides of a charge storage unit, according to embodiments of the present inventive concepts;

FIG. 15 is a cross-sectional view of image sensors, in which a shield metal has a butting contact formed at one side of a charge storage unit, according to other embodiments of the present inventive concepts;

FIG. 16 is a plan view of image sensors according to other embodiments of the present inventive concepts;

FIG, 17 is a plan view of image sensors according to other embodiments of the present inventive concepts; and

FIG. 18 is a block diagram of imaging systems including image sensors, according to embodiments or the present inventive concepts.

### DETAILED DESCRIPTION OF THE EMBODIMENTS

Hereinafter, embodiments of the present inventive concepts will be described in detail with reference to the accompanying drawings. Like reference numerals in the drawings denote like elements, and thus their redundant description will be omitted.

The present inventive concepts will now be described more fully with reference to the accompanying drawings, in which exemplary embodiments of the present inventive concepts are shown. The present inventive concepts may, however, be embodied in many different forms and should not be construed as being limited to the embodiments set forth herein; rather, these embodiments are provided so that this disclosure will be thorough and complete, and will fully convey the present inventive concepts to those of ordinary skill in the art.

It will be understood that although the terms “first”, “second”, etc. are used herein to describe members, regions, layers, portions, sections, components, and/or elements in embodiments of the present inventive concepts, the members, regions, layers, portions, sections, components, and/or elements should not be limited by these terms. These terms are only used to distinguish one member, region, portion, section, component, or element from another member, region, portion, section, component, or element. Thus, a first member, region, portion, section, component, or element described below may also be referred to as a second member, region, portion, section, component, or element without departing from the scope of the present inventive concepts. For example, a first element may also be referred to as a second element, and similarly, a second element may also be referred to as a first element, without departing front the scope of the present inventive concepts.

Unless otherwise defined, all terms (including technical and scientific terms) used herein have the same meaning as commonly understood by those of ordinary skill in the art to which the present inventive concepts pertain. It will also be understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

In the accompanying drawings, variations from the illustrated shapes as a result, for example, of manufacturing techniques and/or tolerances, are to be expected. Thus, the embodiments of the present inventive concepts should not be construed as being limited to the particular shapes of regions illustrated herein but may include deviations in shapes that result, for example, from a manufacturing process. As used herein, the term “and/or” includes any and all combinations of one or more of the associated listed items.

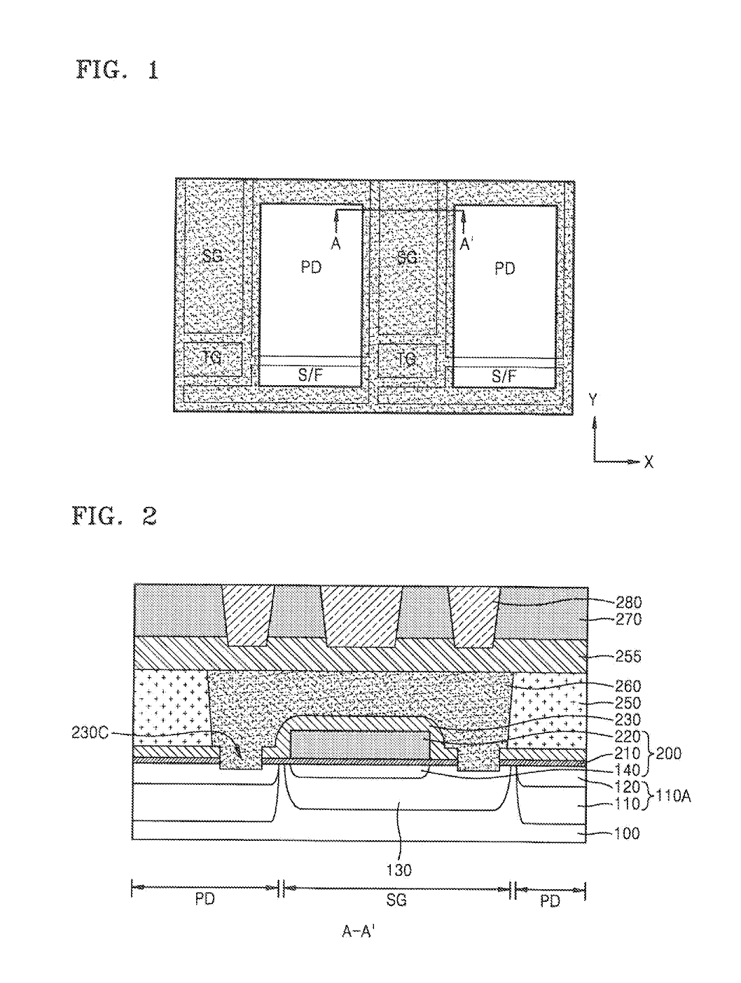

FIG. 1 is a plan view of image sensors according to embodiments of the present inventive concepts.

Referring to FIG. 1, the image sensors can include a photodiode PD, a storage gate SG, a transfer gate TG, and a source/follower gate S/F.

FIG. 2 is a cross-sectional view of the image sensors, in which a shield metal has a butting contact formed at both sides of a charge storage unit, according to embodiments of the present inventive concepts.

Specifically, FIG. 2 corresponds to a schematic cross-sectional view taken along the line A-N of FIG. 1, A photodiode 110A can include a P-type region 120 and an N-type region 110. A storage diode 140 of a charge storage unit 200 can include an N-type region that may temporarily maintain charges generated by the photodiode 110A. A shield metal 260 may be formed to surround the charge storage unit 200 and may contact an ion implantation region in a butting contact method.

In the example embodiment, the photodiode 110A and the storage diode 140 may be disposed in a P-type well. The P-type well may be formed at one side portion of an N-type substrate by on implantation or epitaxial growth. A P-type substrate may be used instead of the N-type substrate in which the P-type well is formed.

The shield metal 260 can reduce or completely block light incident on the charge storage unit 200. The shield metal 260 may be biased to a fixed voltage, such as a power supply voltage or a ground voltage, to prevent the shield metal 260 from causing a coupling with other signal lines. Accordingly, in conventional technologies, a contact process is generally performed on the shield metal 260. However, in this case, excessive ions may be implanted in the shield metal 260, which is floated, during the contact process, and thus, arcing may occur in facilities or plasma damage to a device under the shield metal 260 may occur.

In an example embodiments of the present inventive concepts, a contact 230C for fixing a bias of the shield metal 260 may not be formed in an upper portion of the shield metal 260 but may be formed, in a butting contact structure, in a lower portion of the shield metal 260. In this case, ions may not be implanted through an upper contact process unlike conventional technologies, and thus, arcing may be reduced or may not occur in facilities and plasma damage to a device under the shield metal 260 may be reduced or may not occur.

In addition, as the contact 230C (hereinafter, referred to as a butting contact 230C) is formed to surround the charge storage unit 200, the influence of incident light on the charge storage unit 200 may be reduced or prevented. That is, in conventional technologies, the shield metal 260 may cover only an upper surface of the charge storage unit 200, and thus, incident light may be reflected in an internal device and thus be input to the storage diode 140 through the side of the charge storage unit 200. In this case, the level of a signal may be changed. In addition, in conventional technologies, an additional process may be required to form a contact in an upper portion of the shield metal 260. However, in the example embodiments of the present inventive concepts, the butting contact 230C may be formed in a lower portion of the shield metal 260 to simplify processes, and a stable and uniform bias may be obtained by a great number of contacts that may be formed in the entire image sensor.

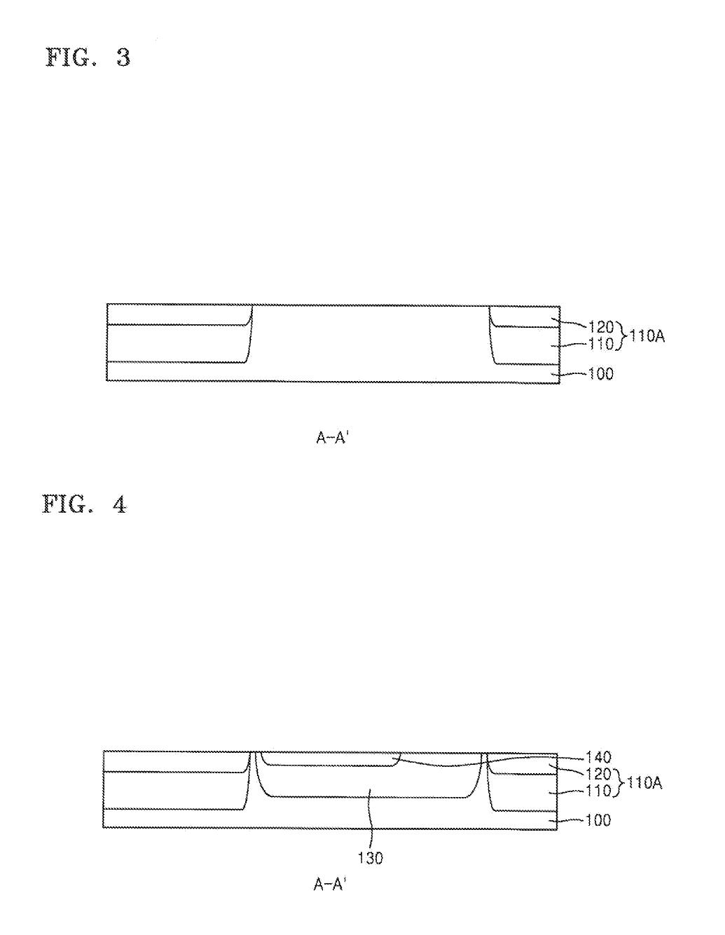

FIGS. 3 through 14 are diagrams that sequentially illustrate methods of manufacturing image sensors, in which a shield metal has a butting contact formed at both sides of a charge storage unit, according to embodiments of the present inventive concepts.

Referring to FIG. 3, a photodiode 110A, including an N-type region 110 and a P-type region 120, may be formed. The N-type region 110 may be formed in a substrate 100, and the P-type region 12.0 may be formed around a surface of the substrate 100. To make an active layer, a well layer may be formed in the substrate 100 by implanting ions. The well layer may be formed through processes of implanting phosphorus (P) ions to form the N-type region 110 for electron collection and implanting boron (B) ions to form the P-type region 120 around the surface of the substrate 100. The P-type region 120 can reduce or prevent the inflow of electrons from the surface of the photodiode 110A to reduce a dark current.

Referring to FIG. 4, a channel stop region 130 may be formed at one side of the photodiode 110A and a storage diode 140 may be formed on the surface of the substrate 100. The channel stop region 130 that is a P-type channel stop region may be formed through an ion implantation process to block the movement of electrons between channels, and the storage diode 140 that is an N-type storage diode may be formed on an upper surface of the channel stop region 130 through an ion implantation process. The storage diode 140 may be a temporary charge storage and can store charges while the photodiode 110A receives light to collect signals.

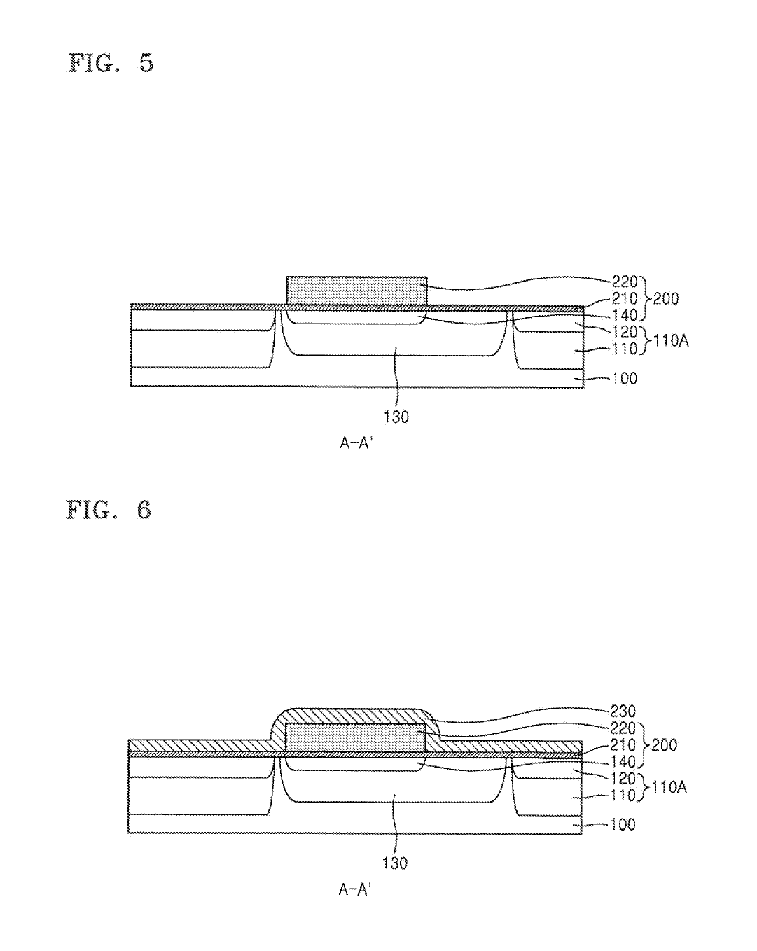

Referring to FIG. 5, a gate dielectric film 210 may be formed on the surface of the substrate 100 and a storage gate 220 may be formed in a region corresponding to the storage diode 140. The gate dielectric film 210 may include at least one selected from a silicon oxide film, a silicon nitride film, a silicon oxynitride film, an oxide/nitride/oxide (ONO) film, and a high-k dielectric film having a dielectric constant that is higher than that of the silicon oxide film. The storage gate 220 may include at least one selected from a semiconductor doped with impurities, a metal, a conductive metal nitride, and a metal silicide. That is, a charge storage unit 200 can form a metal oxide semiconductor (MOS) capacitor that includes the storage diode 140, the gate dielectric film 210, and the storage gate 220.

Referring to FIG. 6, an upper insulating film 230 may be formed to cover the storage gate 220 and the gate dielectric film 210. The upper insulating film 230 may be formed of SiN but is not limited thereto.

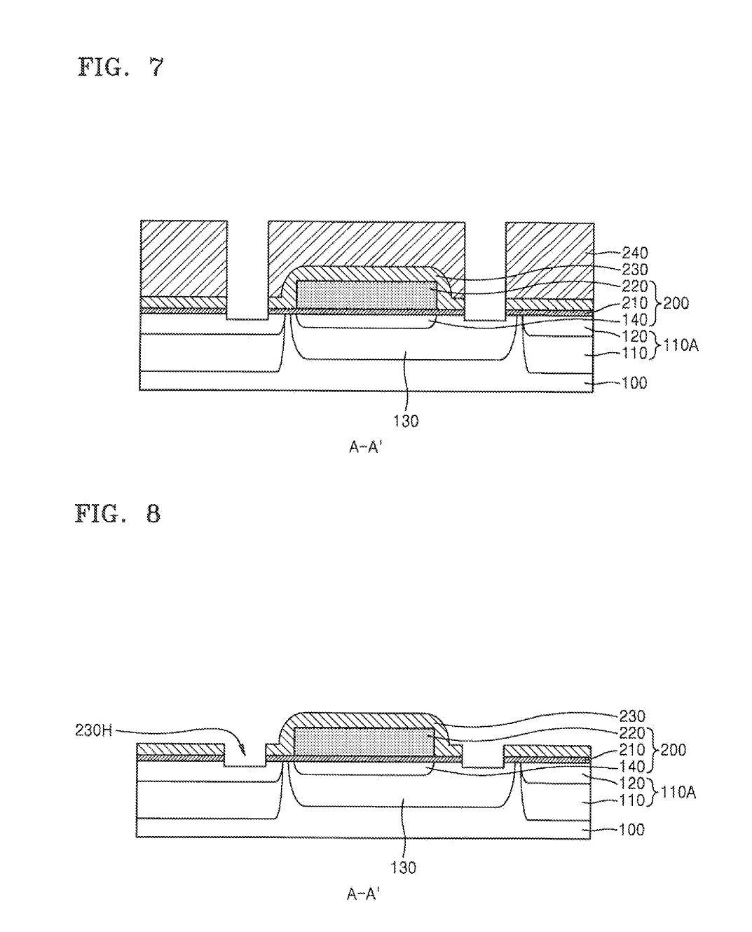

Referring to FIG. 7, a portion of the gate dielectric film 210 and a portion of the upper insulating film 230 may be removed through a photolithography process. Specifically, a photosensitive film 240 may be formed on the upper insulating film 230, a portion of the photosensitive film 240 may be removed through a lithography process, and then the portion of the gate dielectric film 210 and the portion of the upper insulating film 230 may be removed through an etching process by using the photosensitive film 240 as a mask. A recess may be formed by excessively etching the upper surface of the substrate 100 during the etching process. The recess may be for widening a junction portion of a shield metal having a butting contact structure and forming a butting contact at a level, which is lower than that of the upper surface of the substrate 100, to prevent or reduce incident light from being reflected and input to the side of the storage diode 140. The photosensitive film 240 may be removed after the photolithography process.

Referring to FIG. 8, a hole 230H for a butting contact of a shield metal may be formed in the gate dielectric film 210 and the upper insulating film 230. Although not illustrated in FIG. 8, the hole 230H may be formed by excessive etching so that a recess is formed, as explained above,

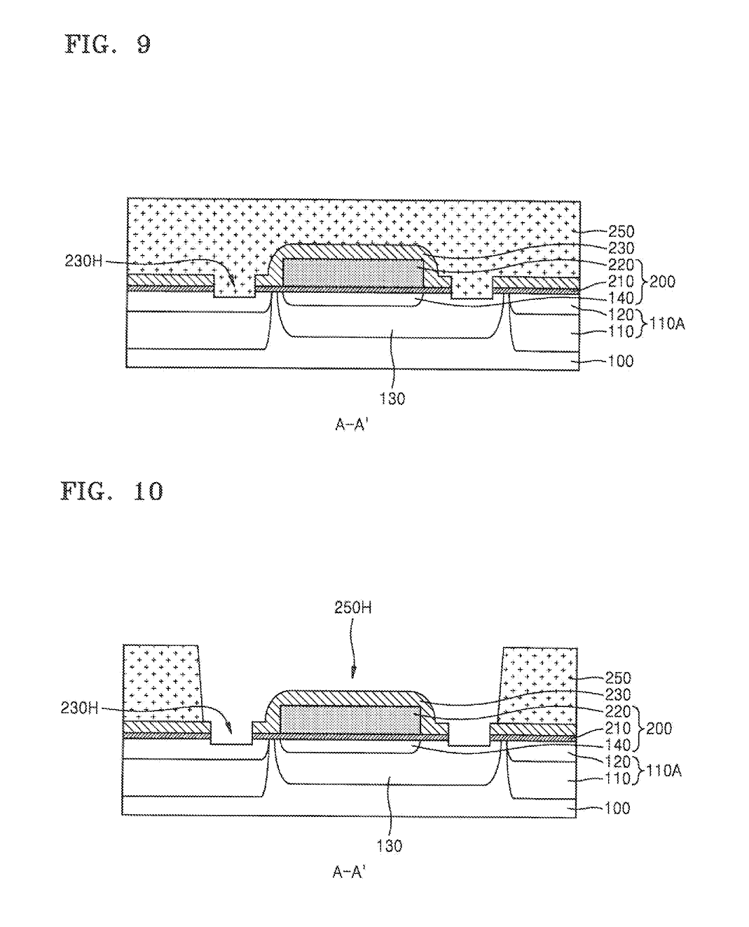

Referring to FIG. 9, an interlayer dielectric (ILD) film 250 may be formed. The ILD film 250 may be formed of at least one selected front flowable oxide (FOX), high density plasma (HDP) oxide, tonen silazene (TOSZ), spin on glass (SOG), and doped silica glass (USG). However, the materials of the ILD film 250 are not limited hereto.

Referring to FIG. 10, a space 250H, in which a shield metal is to be deposited, may be formed by etching the ILD film 250. Since the shield metal may contact an ion implantation region of the substrate 100, an etching process may be performed so that the ILD film 250 may be etched up to a region, in which the surface of the substrate 100 is exposed, or a recess may be formed.

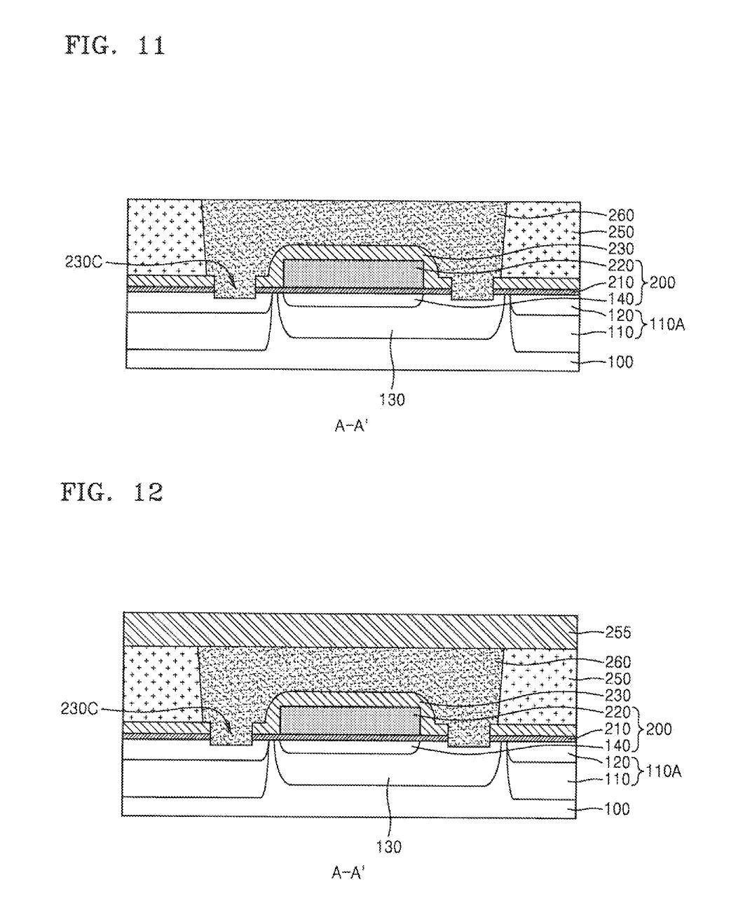

Referring to FIG. 11, planarization may be performed by using an etch-back process or a chemical mechanical polishing (CMP) process after depositing a shield metal 260. The shield metal 260 may be formed to cover the upper surface of the charge storage unit 200 and also to reduce or block the inflow of light that is reflected to the side of the charge storage unit 200 through the butting contact 230C. A level of a lower surface of a portion in which the shield metal 260 contacts the substrate 100 may be lower than a level of the upper surface of the substrate 100. This structure may be formed by making a recess via excessive etching in the process of forming a hole for the butting contact 230C and then depositing the shield metal 260, as explained above.

The portion in which the shield metal 260 contacts the substrate 100 may be a portion of a region in which the photodiode 110A is formed. Since the storage diode 140 is positioned at one side of the photodiode 110A, a region in which the butting contact 230C is formed may be a portion of the region in which the photodiode 110A is formed.

In addition, the portion in which the shield metal 260 contacts the substrate 100 may be a region doped with P-type impurities or a region doped with N-type impurities. Since a bias of the shield metal 260 may be fixed through the butting contact 230C, the butting contact 230C may contact a doped region through which a current flows. When the substrate 100 is doped with P-type impurities, the shield metal 260 may be connected to a ground voltage. When the substrate 100 is doped with N-type impurities, the shield metal 260 may be connected to a bias voltage.

The butting contact 230C may be formed around an edge of the shield metal 260 or may be formed in a region that is separate from the edge of the shield metal 260. That is, the butting contact 230C may contact the upper surface of the substrate 100 and may surround the charge storage unit 200. However, a position in which the butting contact 230C is formed is not limited to an edge region of the shield metal 260.

Referring to FIG. 12, an upper ILD film 255 may be formed on an upper surface of the shield metal 260. The upper ILD film 255 may be formed so that the shield metal 260 may be separate from other metal interconnection lines. The upper ILD film 255 may include the same material as the ILD film 250 or a material that is different from that of the ILD film 250.

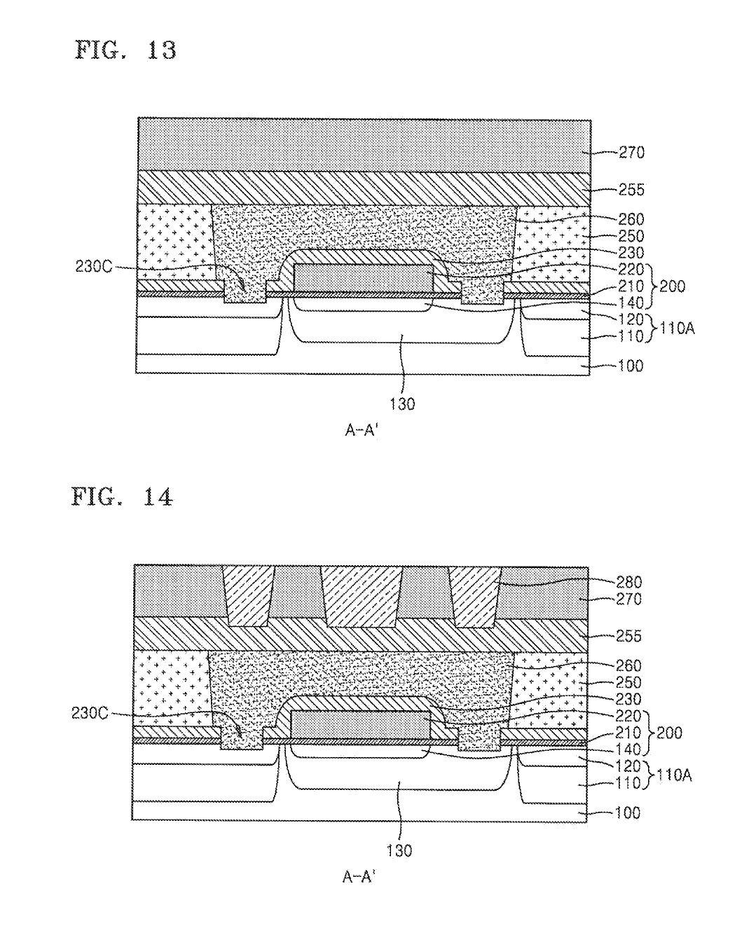

Referring to FIG. 13, an inter-metal dielectric (IMD) film 270 may be formed on an upper surface of the upper ILD film 255, The IMD film 270 may provide insulation between metal interconnection lines.

Referring to FIG. 14, the IMD film 270 may be partially etched and a metal interconnection line 280 may be formed. As a result, image sensors according to the example embodiments of the present inventive concepts illustrated in FIG, 2 may be obtained.

As described above with reference to FIG. 2, the photodiode 110A can include the P-type region 120 and the N-type region 110. The storage diode 140 of the charge storage unit 200 can include an N-type region that may temporarily maintain charges generated by the photodiode 110A. The shield metal 260 may be formed to surround the charge storage unit 200 and may contact an ion implantation region in a butting contact method.

In example embodiments of the present inventive concepts, the butting contact 230C for fixing a bias of the shield metal 260 may not be formed in an upper portion of the shield metal 260 but may be formed in a lower portion of the shield metal 260. In this case, ions may not be implanted through an upper contact process unlike conventional technologies, and thus, arcing may be reduced or may not occur in facilities and plasma damage to a device under the shield metal 260 may be reduced or may not occur.

In addition, as the butting contact 230C may be formed to surround the charge storage unit 200, the influence of incident light on the charge storage unit 200 may be reduced or prevented.

In addition, in example embodiments of the present inventive concepts, the butting contact 230C may be formed in a lower portion of the shield metal 260 to simplify processes, and a stable and uniform bias may be obtained by a great number of contacts that may be formed in the entire image sensor.

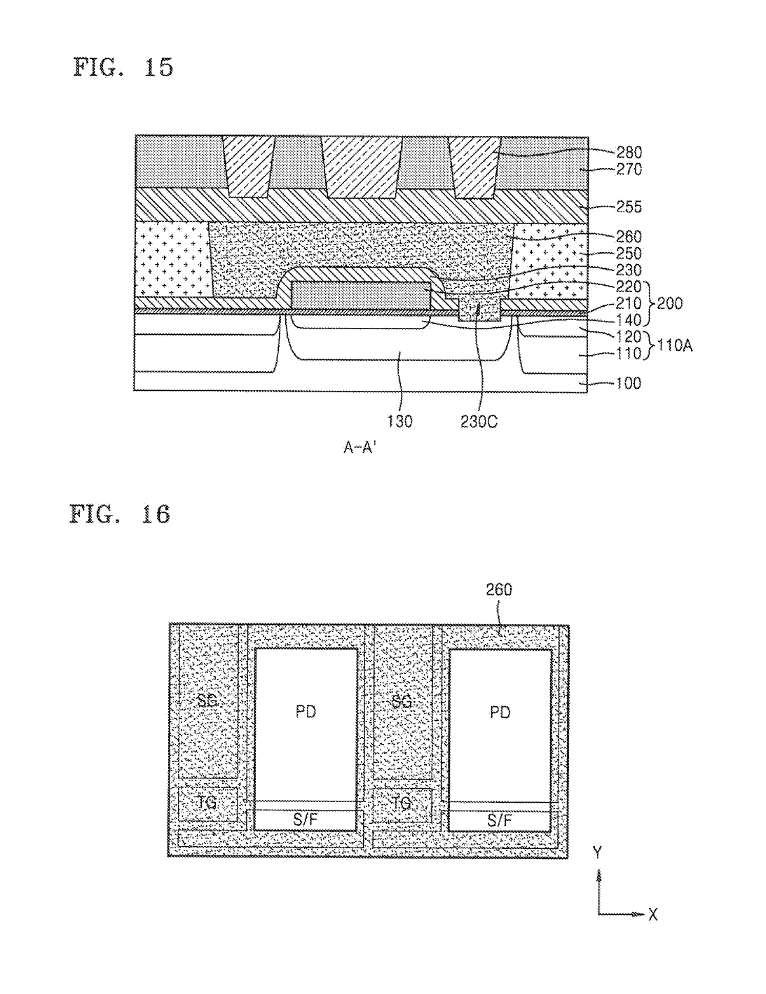

FIG. 15 is a cross-sectional view of image sensors, in which a shield metal has a butting contact formed at one side of a charge storage unit, according to other embodiments of the present inventive concepts.

Referring to FIG. 15, a butting contact 230C of a shield metal 260 may be formed only at one side of a charge storage unit 200. Specifically, the butting contact 230C may be formed only at one side of the charge storage unit 200 to improve the light-receiving efficiency of the image sensor without forming a contact in a portion of a photodiode 110A.

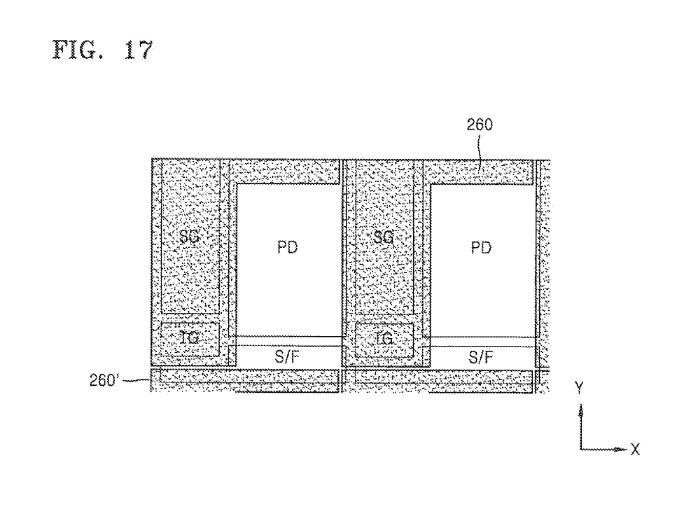

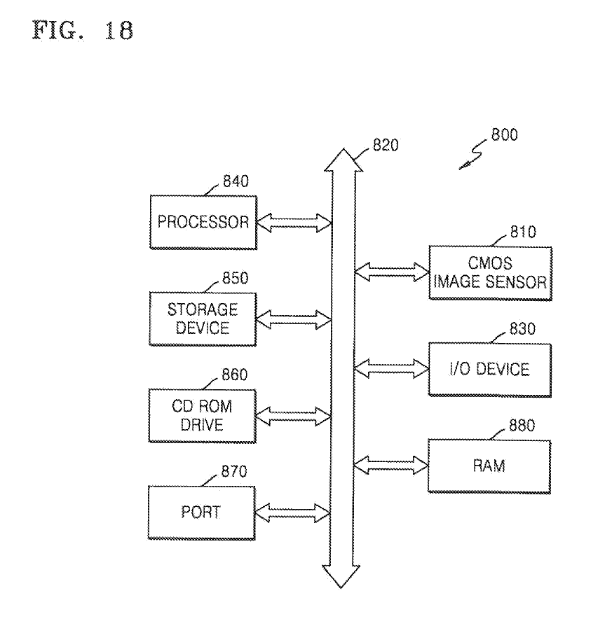

FIG. 16 is a plan view of image sensors according to other embodiments of the present inventive concepts.

Referring to FIG. 16, a shield metal 260 can extend without disconnection in a first direction (X direction) and a second direction (Y direction). When the shield metal 260 is formed to extend without disconnection, like a metal interconnection line, a shading of a screen may be reduced since a bias voltage of the shield metal 260 is stably applied to all pixels. Thus, the interconnection line such as a ground line may be reduced.

FIG. 17 is a plan view of image sensors according to other embodiments of the present inventive concepts.

Referring to FIG. 17, a shield metal 260 can surround a charge storage unit and may be separate from an adjacent shield metal 260′. The shield metal 260 can reduce or block light from reaching the charge storage unit under the shield metal 260.

FIG. 18 is a block diagram of imaging systems 800 including an image sensor 810, according to embodiments of the present inventive concepts.

Referring to FIG. 18, imaging systems 800 are systems for processing an output image of the image sensor 810.

The imaging system 800 includes a processor 840 that may communicate with an input/output (I/O) device 830 via a bus 820. In some embodiments, the processor 840 may be, for example, a microprocessor or a central processing unit (CPU). In the imaging system 800, the processor 840 may communicate with a storage device 850, a CD-ROM drive 860, a port 870, or RAM 880 via the bus 820 and thus may reproduce an output image for data of the image sensor 810.

The port 870 may be a port that may be coupled, for example, to a video card, a sound card, a memory card, or a universal serial bus (USB) device or may communicate with another system. in some embodiments, the image sensor 810 may be integrated together with the processor 840. In some embodiments, the image sensor 810 may be integrated together with the RAM 880. In some embodiments, the image sensor 810 may be integrated with the processor 840 as a chip that is separate from the processor 840.

The imaging system 800 may be applied to various devices, such as digital cameras, camcorders, mobile phones, game consoles, security cameras, medical micro cameras, and robots, to name just a few.

Embodiments of the present inventive concepts may provide image sensors in which a shield metal has butting contacts formed at three sides or four sides of a charge storage unit as well as at two sides of the charge storage unit.

While the present inventive concepts have been particularly shown and described with reference to exemplary embodiments thereof, it will be understood that various changes in form and details may be made therein without departing from the spirit and scope of the following claims.

What is claimed is:

1. An image sensor comprising:
a photodiode in a substrate, the photodiode configured to generate signal charges based on incident light;
a charge storage unit positioned at a side of the photodiode, the charge storage unit configured to temporarily store the signal charges generated by the photodiode;
a transfer gate configured to transfer the signal charges stored in the charge storage unit; and
a shield metal on the charge storage unit and contacting the substrate.

2. The image sensor of claim 1, wherein the shield metal contacts the substrate at a side of the charge storage unit.

3. The image sensor of claim 1, wherein the shield metal contacts the substrate at more than one side of the charge storage unit.

4. The image sensor of claim 1, wherein a level of a lower surface of a portion of the shield metal which contacts the substrate is lower than a level of an upper surface of the substrate.

5. The image sensor of claim 1, wherein the shield metal contacts the substrate at a region in which the photodiode is formed.

6. The image sensor of claim 1, wherein the shield metal is arranged to extend continuously in a first direction and a second direction.

7. The image sensor of claim 1, wherein the shield metal surrounds the charge storage unit and is separate from an adjacent shield metal.

8. The image sensor of claim 1, wherein the shield metal is connected to a ground voltage when the substrate is doped with P-type impurities.

9. The image sensor of claim 1, wherein the shield metal is connected to a bias voltage when the substrate is doped with N-type impurities.

10. The image sensor of claim 1, wherein the charge storage unit is a metal oxide semiconductor (MOS) capacitor.

11. An image sensor comprising:
a photodiode in a substrate;
a charge storage unit in the substrate, the charge storage unit configured to temporarily store signal charges transmitted from the photodiode; and
a shield metal on the charge storage unit and on the substrate,
wherein the shield metal contacts the substrate via a butting contact.

12. The image sensor of claim 11, wherein the butting contact contacts the substrate at a side of the charge storage unit.

13. The image sensor of claim 11, wherein the butting contact contacts the substrate at more than one side of the charge storage unit.

14. The image sensor of claim 11, wherein the butting contact is formed adjacent an edge of the shield metal.

15. The image sensor of claim 11, wherein a region in which the butting contact contacts the substrate is a doped region.

16. An image sensor comprising:
a substrate;
a photodiode in the substrate;
a charge storage unit in the substrate and adjacent the photodiode;
a gate dielectric film on the substrate;
a shield metal on the charge storage unit and on the substrate, wherein portions of the shield metal perforate the gate dielectric film; and
a channel stop region below the gate dielectric film and contacting lower portions of the charge storage unit, wherein the shield metal contacts the channel stop region.

17. The image sensor of claim 16, wherein the channel stop region is a doped region configured to reduce the movement of electrons between channels.

18. The image sensor of claim 16, wherein the shield metal perforates the gate dielectric film in at least two regions.

19. The image sensor of claim 16. further comprising an upper insulating film on an upper portion of the charge storage unit and on the photodiode, wherein the shield metal perforates the upper insulating film.

20. The image sensor of claim 16, wherein the shield metal defines a butting contact that contacts a doped region of the substrate below the gate dielectric film, and wherein an electrical connection of the shield metal corresponds to a type of doping impurities used in the doped region.
